(19) United States
(12) Patent Application Publication
(10) Pub. No.: US 2025/0146711 A1
(43) Pub. Date: May 8, 2025

(54) SPECTRALLY SELECTIVE ABSORBING COATING FOR SOLAR RECEIVERS ACTING IN AIR

(71) Applicant: ENEA - Agenzia nazionale per le nuove tecnologie, l'energia e lo sviluppo economico sostenibile, Roma (IT)

(72) Inventors: Antonio D'ANGELO, Roma (IT); Claudia DILETTO, Roma (IT); Salvatore ESPOSITO, Roma (IT); Giorgio GRADITI, Roma (IT); Antonio GUGLIELMO, Roma (IT); Michela LANCHI, Roma (IT)

(73) Assignee: ENEA - Agenzia nazionale per le nuove tecnologie, l'energia e lo sviluppo economico sostenibile, Roma (IT)

(21) Appl. No.: 18/867,906

(22) PCT Filed: Jun. 5, 2023
(86) PCT No.: PCT/EP2023/064952

§ 371 Date: Nov. 21, 2024

(30) Foreign Application Priority Data
Jun. 7, 2022 (IT) 102022000012065

(51) Int. Cl. F24S 70/225; C23C 14/02; C23C 14/08; C23C 14/18; F24S 70/25; F24S 80/00

(52) U.S. Cl. CPC F24S 70/225; F24S 70/25; C23C 14/02; C23C 14/081; C23C 14/18; F24S 2080/011

(57) ABSTRACT

A spectrally selective absorbing coating for receivers acting in air of thermal and thermodynamic solar systems having a substrate and at least a protective structure capable of protecting the metal component of the protective structure and the metal components of the absorbing coating against the atmospheric oxidizing agents, the protective structure which in turn includes a metal layer upon which a ceramic layer is arranged.

### CROSS-REFERENCE TO RELATED APPLICATIONS

This application is a 371 National Phase of PCT/EP2023/064952, filed Jun. 5, 2023, which claims priority from Italian Patent Application No. 102022000012065, filed Jun. 7, 2022, both of which are incorporated herein by reference as if fully set forth.

### TECHNICAL FIELD

The present invention relates to a spectrally selective absorbing coating for receivers acting in air and, in particular, for receiver tubes acting in air of solar thermal and thermodynamic systems for the production of thermal and/or electric energy, with special reference to the solar thermal and thermodynamic with parabolic or Fresnel linear collector concentrating systems. The receiver of these systems has tubular geometry, and it has to absorb the highest possible amount of solar radiation concentrated thereon and, at the same time, to disperse towards the external environment the least possible amount of heat.

### BACKGROUND

Such function is performed by a particular surface coating applied on the tube, typically made of steel, in which a heat transfer fluid flows; said tube is designated hereinafter even with the wording “substrate” in relation to the fact that a coating is applied thereon.

In order to effectively fulfil such function, the surface coating of the receiver has to show reflectance optical properties varying depending upon the wavelength. In particular, in order to obtain a solar receiver having high photo-thermal efficiency, the coating has to show a behaviour as close as possible to the ideal one, that is zero reflectance (unitary absorbance) in the spectral region of the solar radiation (0.3-2.0 μm) and unitary reflectance (zero absorbance and emissivity) in the spectral region of the thermal infrared (wavelength 2.0-40.0 μm), with a step transition (cut-off) between the two regions.

Following this, when one refers to the this kind of coating, the use of the term “spectrally selective absorbing coating” for solar receivers is established. In order to obtain such behaviour, the spectrally selective absorbing coating is generally formed by a complex multi-layered structure, having in sequence, starting from the substrate, a reflector in the infrared region, an absorber of the solar radiation and, at last, an anti-reflective coating to minimize the losses by reflection of the solar radiation. Each one of the above-mentioned elements (infrared reflective coating, solar absorber, anti-reflective coating) of the absorbing coating consists of one or more layers of materials suitably selected so that their optical properties concur in reaching the wished performances of high solar absorbance (αₛ) and low thermal emissivity (εₜₕ) at the operating temperatures of the receiver that is, as a whole, of high efficiency in the photo-thermal conversion (ηₚₜ) of the absorbing coating.

In particular, the solar radiation is generally absorbed by means of composite materials of Cermet type, consisting of a ceramic phase and a metal phase. Such materials allow to have high absorptions in the spectral region of the solar radiation and a good transparency in the spectral region of the thermal infrared, by giving to the coating a behaviour close to the ideal one.

The receiver tube acting in air can consist only of the steel tube coated with the absorbing coating (not incapsulated receiver tube) or of the steel tube coated with the incapsulated absorbing coating by means of an external tube made of glass (incapsulated receiver tube). In both cases, the coating is in contact with air, therefore it is subjected to degradation mechanisms accelerated by phenomena of oxidative type involving the metal portions of the coating with consequent deterioration of the photo-thermal performances.

These phenomena negatively affect the durability of the absorbing coating and the higher the operation temperature of the receiver tube is, the more the phenomena become relevant.

The spreading of the technology of the receiver tubes in air, both the not incapsulated ones and the incapsulated ones, was strongly limited due to the difficulty in implementing receiver tubes operating at average (400° C.) and high temperature (550° C.), with photo-thermal performances and durability comparable to those of the more expensive incapsulated and evacuated receiver tubes.

An example of solution to the above-mentioned technical problem is provided in the international application n. WO 2022/024064 A1, disclosing a solar absorber coating capable to increase the structure stability of the medium-high reflectance metals, thereby a solar absorber coating is obtained with improved photothermal performances at high temperatures.

Moreover, in the art, several publications can be found describing both solar absorbing coatings using metal components capable of resisting to oxidation, such as the self-passivating alloys, and absorbing coatings incapsulated by dense layers with the double function of anti-reflective filter and oxidation barrier.

In this last case, the solutions to be adopted to implement these coatings are very complex and expensive and the required deposition processes have a high cost, not compatible with the industrial production.

### SUMMARY

The technical problem underlying the present invention is to provide a spectrally selective absorbing coating, a receiver using it and a process for its implementation, so to avoid the drawbacks mentioned with reference to the state of the art.

Such problem is solved by an absorbing coating as above specified, a receiver and an implementation process as defined herein.

The main advantage of the spectrally selective absorbing coating according to the invention lies in comprising one or more structures capable of protecting their metal component and the metal components of the absorbing coating against the atmospheric oxidizing agents by making it suitable to operate directly in air for use temperatures up to 1200° C.

This protective structure is also suitable to be implemented with the same deposition techniques used to implement the different portions of the absorbing coating which are: the physical vapour deposition (PVD) techniques and, in particular, the techniques of high repeatability and productivity sputtering type.

### BRIEF DESCRIPTION OF THE DRAWINGS

The present invention will be described hereinafter according to some preferred embodiments, provided by way of example and not for limitative purposes with reference to the enclosed drawings wherein:

FIG. 1 shows a schematic section view of a protective structure of an absorbing receiver according to the invention;

FIG. 2 shows a schematic section view of a first embodiment of absorbing coating according to the invention;

FIG. 3 shows a schematic section view of a second embodiment of absorbing coating according to the invention;

FIG. 4 shows a schematic section view of a third embodiment of absorbing coating according to the invention; and

FIG. 5 shows a diagram illustrating the reflectance course of the protective structure deposited on steel substrate in the spectral range of 250-2500 nm.

### DETAILED DESCRIPTION

In the drawings, for a simpler and clearer representation, the shown elements were not necessarily drawn to scale.

With reference to figures, the present invention relates to a spectrally selective absorbing coating for receivers acting in air of solar thermal and thermodynamic systems, designated as a whole with 2.

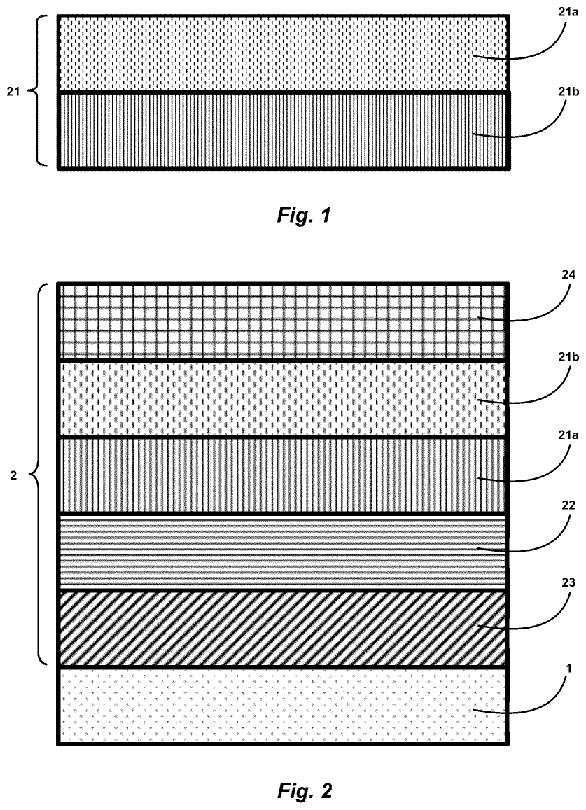

The absorbing coating 2 is arranged in a substrate 1 an, it generally comprises at least a protective structure 21 (FIG. 1) capable of protecting both its metal component and the metal components of said absorbing coating 2 against the atmospheric oxidizing agents; each protective structure 21 of the absorbing coating 2 comprises a metal layer 21a whereon a ceramic layer 21b is arranged.

The metal layer 21a consists of an alloy comprising at least two metals, in particular:
a first metal, present in the metal layer 21a in alloy with atomic percentages comprised between 50% and 90%, selected in the group consisting of: W, Mo, Ta, Nb, Ni, Co, Cu, Hf, Fe, Ag, Au, Pt, Pd, Cr, Rh; and
a second metal, present in the metal layer 21a in alloy with atomic percentages comprised between 10% and 50%, selected in the group consisting of: Cr, Al, Si, Ti, Zr.

Gibbs free energy of the second metal, for the formation of its oxide, has to be lower than that of the first metal.

The ceramic layer 21b comprises a sub-stoichiometric oxide of a metal material, selected in the group consisting of: Al, Si, alloy of Al and Si, Gibbs free energy thereof of formation of its oxide has to be lower than or equal to that of the above-mentioned second metal.

Said metal alloy can include all possible combinations between the first and the second metal, on condition that said metal alloy is not NiCr, HfZr.

The above-described protective structure 21 can operate at an operating temperature, which constitutes a piece of data provided during planning, up to 1200° C., preferably up to 800° C.

The first constituent metal, defined “primary”, must have medium-high reflecting optical features in the spectral range of 2-40 m and it must have a structural and chemical-physical stability at the operating temperature provided for the absorbing coating 2.

The second constituent metal, defined “secondary”, must have the capability of forming, once in contact with oxygen, uniform and compact oxides, particularly stable and resistant to the operating temperature provided for the absorbing coating 2.

The metal layer 21a has to be coated with said ceramic layer 21b which must have the features described hereinafter.

The ceramic layer 21b has a structural and chemical-physical stability in air at the operating temperature provided for the absorbing coating 2, and the oxide of the ceramic layer 21b has to be deposited in sub-stoichiometric form with oxygen atomic percentages which will be decreasing as the operating temperature provided for the absorbing coating 2 increases.

Moreover, as the operating temperature provided for the absorbing coating 2 increases, the atomic percentages of the first metal have to decrease whereas those of the second metal have to increase.

The alloy of the metal layer 21a, apart from the “primary” and “secondary” element, can include a third metal, defined “tertiary”, which has the function of improving the structural stability and the adhesion property of the protective structure 21 at the operating temperature of the absorbing coating 2. The “tertiary” metals to be used for this purpose can be selected in the group consisting of: Y, Ti, Zr, and their atomic percentage within the alloy varies between 1% and 10%.

When the alloy is a ternary alloy, or more, it comprises all possible combinations between the first, the second and the third metal on condition that said metal alloy is not NiCrAlY.

Once the protective structure 21 is exposed to the air at a fixed operating temperature, a required condition so that a barrier oxide layer at the metal layer 21a—ceramic layer 21b interface is formed is that the selective oxidation of the “secondary” metal element only of the alloy at the metal layer 21a—ceramic layer 21b interface takes place.

In this way, an oxide is obtained which can play the role of effective barrier both to the spreading of the oxidising agents existing in the atmosphere in the metal layer 21a and to the spreading of the components of the metal layer 21a in the overlying ceramic layer 21b.

In order to promote, at the operating temperature, the selective oxidation of the “secondary” metal element only of the alloy at the metal layer 21a—ceramic layer 21b interface, one has to select a “secondary” metal element of the alloy having Gibbs free energy of formation of its oxide lower than that of the “primary” metal element, and to manage carefully the amounts of oxygen (main oxidizing agent present in the air) and of the “secondary” metal element of the alloy present at the metal layer 21a—ceramic layer 21b interface.

Practically, in order to have a good selective oxidation, in each moment the oxygen which comes in contact with the surface of the metal layer 21a has to be in equal or lower amount than that of the “secondary” metal present on such surface.

If such condition is not met, the exceeding amounts of oxygen could oxidize other elements of the metal layer 21a, with formation of mixed oxides or oxides rich in the “primary” metal element of the alloy and consequent loss in the features of uniformity, compactness, stability and resistance of the oxides rich in the “secondary” metal element of the alloy.

The management of the amount of oxygen and “secondary” metal element of the alloy present on the surface of the metal layer 21a is implemented by acting directly on the mechanisms and on the kinetics of the oxidation reactions occurring on such surface.

In particular, the formation of the barrier oxide layer mainly consists of two phases: a first phase called transition phase followed by a second phase called stationary phase.

During the transition phase the nucleation and subsequent growth of the barrier layer at the metal layer (21a)—ceramic layer (21b) interface take place. In the present case, the oxidation reaction speed during the transition phase mainly depends upon the oxygen concentration present at the metal layer 21a—ceramic layer 21b interface and upon that which the interface reaches by spreading through the ceramic layer 21b.

The transition phase is followed by the growth stationary phase of the barrier oxide layer during which the interface mainly involved by the oxidation reaction is the metal layer 21a—barrier oxide layer one. In this case, the oxide growth speed always depends upon the oxygen concentration which, this time, has to spread through the ceramic layer 21b and then through the barrier oxide layer which has formed during the transition phase. Consequently, the barrier oxide growth speed in the stationary phase results to be much lower than that observed during the transition phase, since the oxygen amounts reaching the “secondary” metal at the metal layer 21a—barrier oxide layer interface are much lower.

The oxygen amount involved in the several growth phases of barrier oxide layer depend upon the operating temperature of the protective structure 21, the stoichiometry and the thickness of the ceramic layer 21b deposited on the metal layer 21a.

Hereinafter, the reflector in the infrared region 23 of the absorbing coating 2 is meant consisting of one or more layers; analogously, the absorber of the solar radiation 22 and the anti-reflective coating 24 in turn comprise one or more layers.

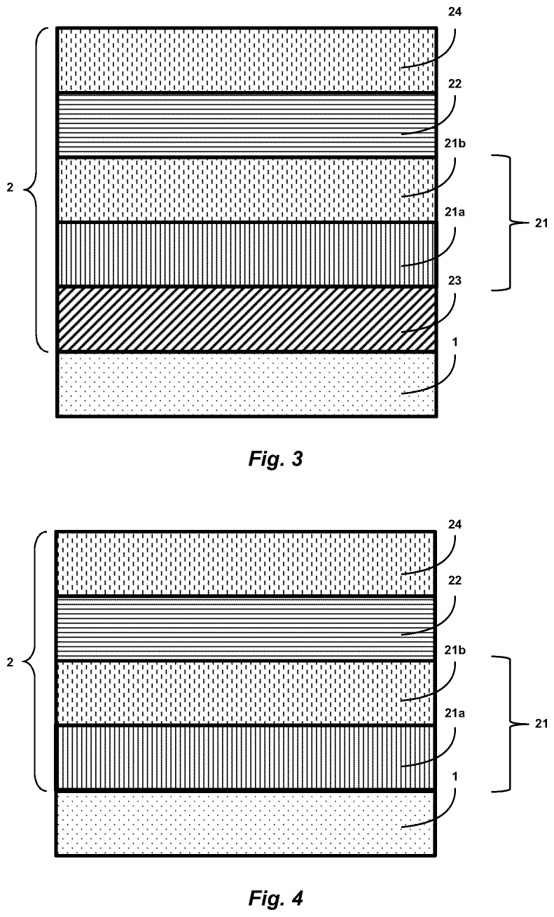

With reference to FIG. 2, a first example of absorbing coating 2 provides said protective structure 21 positioned between the absorber 22 and the anti-reflective coating 24 of an absorbing coating 2 devised to work under vacuum.

In this example, the absorbing coating 2 for receivers acting in air comprises in sequence:
an infrared reflective coating 23 arranged in contact with the substrate 1;
an absorber 22;
a protective structure 21;
an anti-reflective coating 24.

The protective structure 21 protects the metal components of the spectrally selective absorbing coating 2 devised to work under vacuum, consisting of 23, 22 and 24, thus by making it suitable to work in air.

In the proposed sequence, the metal layer 21a of the protective structure 21 participates in the formation of the absorbing element and it has a thickness comprised between 1 and 80 nm, preferably comprised between 10 and 30 nm, so as to be sufficiently thick to guarantee the formation of a barrier oxide at the operating temperature of the absorbing coating 2 and sufficiently thin to allow the different underlying layers to carry out the functions they have been devised for. The ceramic layer 21b of the protective structure 21 participates in the formation of the anti-reflective coating of the absorbing coating 2 and it has a thickness comprised between 1 and 250 nm, preferably between 5 and 60 nm.

In another example, the absorbing coating 2 for receivers acting in air comprises in sequence:
an infrared reflective coating 23 arranged in contact with the substrate 1;
an absorber 22;
a protective structure 21.

In the proposed sequence, the metal layer 21a of the protective structure 21 participates in the formation of the absorbing element and it has a thickness comprised between 1 and 80 nm, preferably comprised between 10 and 30 nm, to guarantee the formation of the barrier oxide and the transparency required to make the underlying layers to carry out the functions they have been devised for. The ceramic layer 21b of the protective structure 21 carries out the anti-reflective function of the absorbing coating 2 and it has a thickness comprised between 1 and 250 nm, preferably between 20 and 120 nm.

With reference to FIG. 3, an additional example of absorbing coating 2 for receivers acting in air comprises in sequence:
an infrared reflective coating 23 arranged in contact with the substrate 1;
a protective structure 21;
an absorber, comprising a metal component consisting of one of the alloys of the metal layer 21a of the protective structure 21 and a ceramic component consisting of one of the oxides of the ceramic layer 21b of the protective structure 21;
an anti-reflective coating 24.

The infrared reflective coating 23 consists in a transition metal selected in the group consisting of: Ti, V, Cr, Zr, Nb, Mo, Hf, Ta, W or a nitride of one of said transition metals. The thickness of the infrared reflective coating 23 is comprised between 1 and 250 nm, preferably between 90 and 150 nm, so as to reflect effectively in the infrared.

In case of operating temperature of the receiver from 600° C. to 800° C., said transition metal can be selected in the group consisting of: Ti, Zr, Mo, W, TiN and ZrN.

The coupling between the protective structure 21 and the infrared reflective coating 23 is preferably implemented, where possible, by selecting the “primary” metal of the alloy constituting the metal layer 21a of the protective structure 21 equal to the one of the metal of the infrared reflective coating 23.

In case of operating temperature of the receiver up to 600° C., the infrared reflective coating 23 comprises the following two layers arranged in sequence:
a barrier layer, arranged in contact with the substrate 1 and with function of barrier and adhesion layer, comprising a transition metal selected in the group consisting of: Ti, V, Cr, Zr, Nb, Mo, Hf, Ta, W or a nitride of one of said transition metals;
a layer consisting of a highly reflective metal selected in the group consisting of: Au, Ag and Cu.

In this way, the advantageous optical behaviour of Au, Ag and Cu can be used and their poor structural and chemical-physical stability at high temperatures, poor adhesion to the substrate 1 and ineffective barrier to the spreading phenomena from the substrate 1 can be compensated by inserting them in the absorbing coating 2 between the barrier layer and the protective structure 21.

When this combination of barrier layer and layer reflecting in the infrared is used, the barrier layer can have a thickness comprised between 1 and 250 nm, preferably between 90 and 150 nm, whereas the layer reflecting in the infrared has a thickness comprised between 1 and 250 nm, preferably between 90 and 150 nm, so as to reflect effectively in the infrared.

The metal layer 21a of the protective structure 21 can have a thickness comprised between 1 and 80 nm, preferably between 10 and 30 nm, so as to be sufficiently thick to guarantee the formation of a barrier oxide at the operating temperature of the absorbing coating 2 and at the same time sufficiently thin to allow the infrared reflective coating 23 to perform its function.

The ceramic layer 21b of the protective structure 21 can have a thickness comprised between 1 and 250 nm, preferably comprised between 5 and 60 nm.

The absorber 22 of the embodiment of FIG. 3 can be formed by one single protective structure 21 or by an alternation of several protective structures 21. The absorber 22, as first layer of said sequence, has the metal layer 21a arranged in contact with the protective structure 21 not belonging to the absorber 22, and as last layer of said sequence it has the ceramic layer 21b arranged in contact with the anti-reflective coating 24.

The absorber 22 can include a minimum number of 2 layers up to a maximum of forty layers.

The metal layer 21a of each protective structure 21 can have a thickness comprised between 1 and 50 nm, preferably between 5 and 20 nm, so as to be sufficiently thick to guarantee both the formation of the barrier oxide at the operating temperature of the absorbing coating 2 and the absorption of the solar radiation. At last, the ceramic layer 21b of the protective structure 21 can have a thickness comprised between 1 and 120 nm, preferably between 10 and 40 nm.

As an alternative to the ceramic-metal multi-layered structure, another example of absorber 22 provides the use of sequences of one or more layers of Cermet material, with a metal component consisting of one of the alloys of the protective structure 21, and a ceramic component consisting of one of the oxides of the protective structure 21.

Each single layer of Cermet material can have a constant volumetric fraction of the metal component, and comprised between 0.01 and 0.49, preferably between 0.10 and 0.35, so that the clusters of the metal alloy are incorporated within the ceramic matrix of oxide type. Moreover, the metal clusters within each Cermet layer will have sizes so as to guarantee both the formation of the barrier oxide layer at the metal clusters-ceramic matrix interface and to have the absorbing function of the Cermet material.

The barrier oxide which forms at the metal clusters—ceramic matrix interface has the function of locking the spreading of the oxidizing agents present in the atmosphere towards the metal components of the absorber 22 and at the same time of locking the spreading of these metal components within the ceramic matrix by preserving the absorbing function of the Cermet layer.

Therefore, the thickness of each Cermet layer has to be comprised between 1 and 200 nm, preferably between 20 and 120 nm.

The absorber 22 can be formed by one single Cermet layer or by several layers until a maximum of twenty. With reference to FIG. 3, the anti-reflective coating 24 consists of a ceramic layer of sub-stoichiometric oxide of Al or Si or an alloy of Al and Si. The oxide of the ceramic layer of the anti-reflective coating 24 is deposited in sub-stoichiometric form so that its microstructure densifies once the absorbing coating 2 is brought at the operating temperature in air. The resulting anti-reflective coating 24 allows to minimize the reflection of the solar radiation incident on the absorbing coating 2, thanks to its dense and compact structure, and to reduce drastically the amounts of oxygen which can reach the absorber 22 and, then, the infrared reflective coating 23.

The thickness of the sub-stoichiometric oxide layer in said antireflective coating 24 is comprised between 1 and 200 nm, preferably between 20 and 120 nm.

Under these conditions, the formation of barrier oxides is favoured, capable of guaranteeing an excellent structural and chemical-physical stability to the absorbing coating 2 in air at the operating temperature.

With reference to FIG. 4, a last example of absorbing coating 2 uses the protective structure 21 directly as infrared reflective coating 23. In particular, the absorbing coating 2 comprises, in sequence:
an infrared reflective coating 23 arranged in contact with the substrate 1, consisting of the metal layer 21a of said protective structure 21, whereon a ceramic layer 21b of the protective structure 21 is placed;
an absorber 22, comprising a metal component consisting of one of the alloys of the metal layer 21a of the protective structure 21 and a ceramic component consisting of one of the oxides of the ceramic layer 21b of the protective structure 21;
an anti-reflective coating 24.

The metal layer 21a which constitutes said infrared reflective coating 23 has a thickness comprised between 50 and 250 nm, preferably between 80 and 200 nm whereas the ceramic layer 21b placed above has a thickness comprised between 1 and 120 nm, preferably between 5 and 50 nm.

The absorber 22 and the anti-reflective coating 24 completing the absorbing coating 2, do not require additional descriptions since they are equal by functions and structure to those of the absorbing coating 2 described in FIG. 3.

According to the invention, a receiver acting in air for solar thermal and thermodynamic systems comprises one of the previously described solar absorbing coatings 2 and, in particular, a receiver tube comprises one of the above-described absorbing coatings 2 arranged on its tubular surface, generally made of steel, acting as substrate 1.

The receiver tube can be incapsulated by means of an additional glass tube comprising an anti-reflective treatment, two glass-metal junctions and elements (bellows) compensating the differential thermal expansions between steel tube and glass tube. The atmospheric air is left in the air gap between the receiver tube and the glass tube.

According to the invention, a process is provided for implementing an above-described absorbing coating on the substrate 1, by means of PVD deposition techniques, and in particular by means of high deposition speed sputtering techniques.

In this case, there may be provided: i) techniques of sputtering and magnetron co-sputtering, in argon, from metal targets ii) techniques of sputtering in argon+reactive gas (nitrogen, oxygen), from metal targets, iii) techniques of reactive magnetron co-sputtering, in argon+oxygen, from metal targets.

Under co-sputtering the simultaneous sputtering, in argon, starting from different material target is meant, whereas under reactive co-sputtering the simultaneous sputtering, in argon+oxygen, starting from different material target, is meant.

The invention can provide that the sputtering depositions are performed at a pressure comprised between 5×10⁻⁴ mbar and 5×10⁻² mbar, preferably between 1×10⁻³ mbar and 2×10⁻² mbar.

A possible thermal pre-treatment of the substrate 1 is implemented under vacuum at a pressure lower than 5×10⁻⁴ mbar, preferably lower than 1×10⁻⁴ mbar, and so as to bring the substrate 1 at a temperature comprised between 100° C. and 300° C. On the contrary, a possible plasma pre-treatment is implemented, typically in Ar gas, at a pressure lower than 5×10⁻² mbar by means of polarization of the substrate 1, or at a pressure lower than 5×10⁻³ mbar by means of an ion source capable of implementing a high-energy ion bombardment of the substrate 1.

The metal layers of the protective structure 21, consisting of an alloy, can be applied by technique of magneton sputtering, in Ar gas, from targets formed by the specific alloy of interest, or by technique of magnetron co-sputtering, in Ar gas, from targets of the single metals composing the alloy; in this second case, the wished composition of the alloy will be obtained by varying suitably the input power of the targets of the single metals.

The ceramic layers 21b of the protective structure 21, consisting of an oxide of Al or Si, can be applied by technique of reactive magnetron sputtering, in Ar gas+O₂, with targets of Al or Si.

The ceramic layers 21b of the protective structure 21, consisting of an oxide of a binary alloy of Al and Si, can be applied by technique of reactive magnetron sputtering, in Ar gas+O₂, from targets formed by the specific alloy of interest, or by technique of reactive magnetron co-sputtering, in Ar gas+O₂, from targets of the single metals constituting the alloy fed with suitable powers.

The metal layers of the infrared reflective coating 23 can be applied by technique of magnetron sputtering, in Ar gas, from targets of the above-mentioned metal.

The layers with metal behaviour of the infrared reflective coating 23, consisting of a nitride of a transition metal, can be applied by technique of reactive magnetron sputtering, in Ar gas+N₂, from targets of the above-mentioned transition metal.

The Cermet layers of the absorber 22 can be applied by means of one of the following techniques:
reactive co-sputtering, that is simultaneous sputtering, in Ar gas+O₂, starting from targets made of different material, with at least a target capable of producing the Cermet metal component and at least a target capable of producing the Cermet ceramic component;
sputtering in Ar gas starting from at least a target capable of producing the Cermet metal component and subsequent reactive sputtering in Ar gas+O₂ starting from at least a target capable of producing the Cermet ceramic component.

In the present case, the Cermet layers, with metal component consisting of an alloy and with ceramic component consisting of an oxide of Al or Si or of an oxide of a binary alloy of Al and Si, can be applied starting from the following targets:

For the alloy deposition:
target of the above-mentioned alloy, or
target of the single metals composing the alloy of interest, fed with a suitable power;

For the deposition of oxide of Al or Si or, respectively, of the oxide of the binary alloy of Al and Si:
target of Al or target of Si, or
target of the above-mentioned binary alloy of Al and Si, or target of Al and Si, fed with a suitable power.

The ceramic layers of the anti-reflective coating 24 of the absorbing coating 2, consisting of an oxide of Al or Si, can be applied by technique of reactive magnetron sputtering, in Ar gas+O₂, from targets of Al or Si.

The ceramic layers of the anti-reflective coating 24, consisting of an oxide of a binary alloy of Al and Si, can be applied by technique of reactive magnetron sputtering, in Ar gas+O₂, from targets formed by the specific alloy of interest, or by technique of reactive magnetron co-sputtering, in Ar gas+O₂, from targets of the single metals composing the alloy fed with suitable powers.

In order to guarantee that, in the absorbing coating 2 the oxides are implemented in sub-stoichiometric form these deposition processes are performed “in transition regime” by means of reactive gas flow control system, in particular by means of control systems of PEM (Plasma Emission Monitoring) or CVM (Cathode Voltage Monitoring) type.

Preferably, said process comprises an additional thermal treatment of the absorbing coating 2 applied on the substrate 1, performed in air or by using gaseous mixtures with controlled oxidative potential and at temperature higher than or equal to 500° C., if the use temperature of a solar receiver comprising said spectrally selective absorbing coating 2 is lower than or equal to 450° C., by increasing the treatment temperature by at least 50° C. with respect to the use temperature of the receiver in case the use temperature of the receiver is higher than 450° C.

With reference to FIG. 1, it illustrates schematically a section view of the protective structure 21 which is constituted by a metal layer 21a made of metal alloy, the constituents thereof have to be at least two elements, whereon a ceramic layer 21b is placed formed by an oxide in sub-stoichiometric form.

The primary metal of the alloy can be selected in the group consisting of: W, Mo, Ta, Nb, Ni, Co, Cu, Hf, Fe, Ag, Au, Pt, Pd, Cr, Rh, whereas the secondary metal can be selected in the group consisting of: Cr, Al, Si, Ti, Zr.

A possible third metal can be provided, which can be selected in the group consisting of: Y, Ti, Zr.

According to a specific example of protective structure 21, the alloy of the metal layer 21a consists of W, Cr and Ti, and the ceramic layer 21b, instead, consists of an oxide of Al.

The following Table I shows the composition of the protective structure 21 in a preferred embodiment thereof.

TABLE I

| | | |
|---|---|---|
| Protective | Metal layer 21a | WCrTi |
| structure 21 | Ceramic layer 21b | AlₓO_{y} |

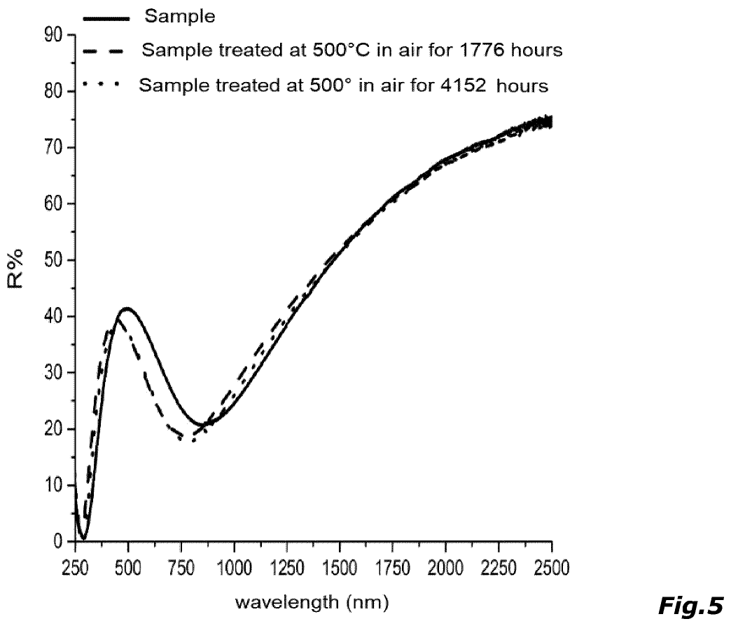

The protective structure 21 with the composition shown in table I was deposited on a substrate 1 made of steel. The metal layer of WCrTi was deposited in contact with the substrate 1 with a thickness of 140 nm, and with the following atomic percentages: 71.8% of W, 27.4% of Cr and 0.8% of Ti. On the metal layer 21a then a ceramic layer 21b of AlₓO_{y} with x=1 and y=1.3, and with a thickness of 100 nm, was deposited. The so constituted protective structure was subjected to two treatments in air at 500° C., the first one lasting 1776 hours, the second one 2376 hours. Before the thermal treatments, and after each thermal treatment, the reflectance of the protective structure 21 in the spectral range of 250-2500 nm was measured and FIG. 5 shows the courses thereof.

From the comparison of the reflectance's, it can be seen that only after the first thermal treatment there is a reflectance variation, mainly due to the formation of the barrier oxide at the metal layer 21a—ceramic layer 21b interface and to the compositional modification of the alumina oxide which transforms in the stoichiometric stable phase.

In the subsequent thermal treatment, no significant variations in the reflectance are noted to show the structural and chemical-physical stability of the protective structure 21.

Therefore, the oxide which forms at the metal layer 21a—ceramic layer 21b interface, carries out effectively the function of barrier to the spreading of the atmospheric oxidizing agents towards the metals of the layer 21a and, at the same time, it prevents these metals from spreading towards the ceramic layer 21b.

Moreover, the invariance of the optical properties of the structure also demonstrates that the growth speed of the barrier oxide at the metal layer 21a-ceramic layer 21b interface is very low. In conclusion, the result of the thermal treatments demonstrates that the protective structure 21 implemented for 500° C. is potentially suitable to carry out the function of barrier to spreading for periods of time compatible with the life cycle of a solar receiver.

To the above-described spectrally selective absorbing coating for receivers acting in air of solar thermal and thermodynamic systems and of the related receiver, a person skilled in the art, with the purpose of fulfilling additional and contingent needs, could introduce several additional modifications and variants, however all within the protective scope of the present invention, as defined by the enclosed claims.

1. A spectrally selective absorbing coating for receivers acting in air in thermal and thermodynamic solar systems, arranged on a substrate, the coating comprising at least one protective structure capable of protecting metal components of said protective structure and of said absorbing coating against the atmospheric oxidizing agents, the coating also comprising a metal layer on which a ceramic layer is arranged, wherein:
said metal layer consists of an alloy of at least a first metal and a second metal, the first metal, present in alloy with atomic percentages comprised between 50% and 90%, being selected from the group consisting of: W, Mo, Ta, Nb, Ni, Co, Cu, Hf, Fe, Ag, Au, Pt, Pd, Cr, Rh, and the second metal, present in alloy with atomic percentages comprised between 10% and 50%, being selected from the group consisting of: Cr, Al, Si, Ti, Zr, said second metal having Gibbs free energy of formation of an oxide thereof lower than that of said first metal; and
said ceramic layer consists of a sub-stoichiometric oxide of a metal material selected from the group consisting of: Al, Si, alloy of Al and Si, said metal material having Gibbs free energy of formation of an oxide thereof lower than or equal to that of said second metal.

2. The absorbing coating according to claim 1, and of a third metal selected from the group consisting of: Y, Ti, Zr, said third metal being present in alloy with atomic percentages comprised between 1% and 10%.

3. The absorbing coating according to claim 1, further comprising in sequence: an infrared reflective coating consisting of one or more layers and arranged in contact with a substrate, an absorber consisting of one or more layers, the protective structure and an anti-reflective coating consisting of one or more layers.

4. The absorbing coating according to claim 3, wherein said metal layer of said protective structure has a thickness comprised between 1 and 80 nm, and said ceramic layer of said protective structure has a thickness comprised between 1 and 250 nm.

5. The absorbing coating according to claim 1, further comprising in sequence: an infrared reflective coating consisting of one or more layers arranged in contact with a substrate, an absorber consisting of one or more layers and the protective structure.

6. The absorbing coating according to claim 5, wherein said protective structure is positioned so as to form a most external portion and in contact with air of said absorbing coating.

7. The absorbing coating according to claim 5, wherein said metal layer of said protective structure has a thickness comprised between 1 and 80 nm, and said ceramic layer of said protective structure has a thickness comprised between 1 and 250 nm.

8. The absorbing coating according to claim 1, further comprising in sequence: an infrared reflective coating consisting of one or more layers and arranged in contact with a substrate, the protective structure, an absorber consisting of one or more layers and an anti-reflective coating consisting of one or more layers.

9. The absorbing coating according to claim 8, wherein said metal layer of said protective structure has a thickness comprised between 1 and 80 nm, and said ceramic layer of said protective structure has a thickness comprised between 1 and 250 nm.

10. The absorbing coating according to claim 8, wherein said infrared reflective coating consists of a layer made of a transition metal selected from the group consisting of: Ti, V, Cr, Zr, Nb, Mo, Hf, Ta, W or of a nitride of one of said transition metals, with a thickness comprised between 1 and 250 nm.

11. The absorbing coating according to claim 8, wherein said infrared reflective coating for operating temperatures up to 600° C. consists of a first barrier layer implemented with a transition metal selected from the group consisting of: Ti, V, Cr, Zr, Nb, Mo, Hf, Ta, W or of a nitride of one of said transition metals, with a thickness comprised between 1 and 250 nm, and of a second layer reflecting in the infrared implemented with a metal selected from the group consisting of: Au, Ag and Cu, with a thickness comprised between 1 and 250 nm.

12. The absorbing coating according to claim 1, further comprising in sequence: an infrared reflective coating consisting of said protective structure arranged in contact with a substrate, an absorber consisting of one or more layers and an anti-reflective coating consisting of one or more layers.

13. The absorbing coating according to claim 12, wherein said metal layer of said protective structure has a thickness comprised between 50 and 250 nm, and said ceramic layer of said protective structure has a thickness comprised between 1 and 120 nm.

14. The absorbing coating according to claim 8, wherein the absorber consists of a sequence of one or more pairs formed by the metal layer and by the ceramic layer, wherein a first one of the layers of said sequence is arranged in contact with the protective structure and a last one of the layers of said sequence is arranged in contact with said anti-reflective coating.

15. The absorbing coating according to claim 14, wherein said metal layers of said absorber have a thickness comprised between 1 and 50 nm, and said ceramic layers of said absorber have a thickness comprised between 1 and 120 nm.

16. The absorbing coating according to claim 14, wherein the absorber consists of a number of layers comprised between 2 and 40.

17. The absorbing coating according to claim 8, wherein said absorber consists of a sequence of one more layers of cermet material consisting of a metal component consisting of the alloy of the metal layer, and of a ceramic component consisting of one of said oxides of the ceramic layer, wherein the metal component is dispersed inside the ceramic component acting as a matrix.

18. The absorbing coating according to claim 17, wherein said one or more layers of cermet material of said absorber have a volumetric fraction of said metal component constant in a single one of the layers of the cermet material and comprised between 0.01 and 0.49.

19. The absorbing coating according to claim 17, wherein said one or more cermet layers of said absorber have a thickness comprised between 1 and 200.

20. The absorbing coating according to claim 17, wherein the absorber consists of a number of the layers comprised between 1 and 20.

21. The absorbing coating according to claim 20, wherein the anti-reflective coating consists of a layer consisting of a sub-stoichiometric oxide of Al or Si or an alloy of Al and Si, with a thickness comprised between 1 and 200 nm.

22. A receiver acting in air for solar thermal and thermodynamic systems, comprising a substrate and the spectrally selective absorbing coating according to claim 1.

23. A process for implementing a spectrally selective absorbing coating, for receivers acting in air of solar thermal and thermodynamic systems, the process comprising the steps of:
providing a substrate of the receiver;
applying a spectrally selective absorbing coating overall or on a portion of a surface of the substrate by PVD deposition techniques,
wherein a metal layer of a protective structure of the coating consists of an alloy of at least a first and a second metal, the first metal, present in alloy with atomic percentages comprised between 50% and 90%, being selected from the group consisting of: W, Mo, Ta, Nb, Ni, Co, Cu, Hf, Fe, Ag, Au, Pt, Pd, Cr, Rh, and the second metal, present in alloy with atomic percentages comprised between 10% and 50%, being selected from the group consisting of: Cr, Al, Si, Ti, Zr, said second metal having Gibbs free energy of formation of an oxide thereof lower than that of said first metal, and wherein, the ceramic layer of the protective structure, deposited on said metal layer, consists of a sub-stoichiometric oxide of a metal material selected from the group consisting of: Al, Si, alloy of Al and Si, said metal material having Gibbs free energy of formation of an oxide thereof lower than or equal to that of said second metal.

24. The process according to claim 23, wherein said process comprises at least one thermal and/or plasma pre-treatment type or by means of plasma or a combination thereof of the substrate, which precedes application of the absorbing coating with the PVD deposition techniques.
